(19) United States
(12) Patent Application Publication
(10) Pub. No.: US 2015/0107617 A1
(43) Pub. Date: Apr. 23, 2015

(54) METHOD OF CLEANING PHOTOMASK

(71) Applicant: SAMSUNG ELECTRONICS CO., LTD., Suwon-si (KR)

(72) Inventors: Sang-Hyeon LEE, Hwasung-City (KR); Hwa-Sung KIM, Hwasung-City (KR)

(73) Assignee: SAMSUNG ELECTRONICS CO., LTD., Suwon-si (KR)

(21) Appl. No.: 14/285,771

(22) Filed: May 23, 2014

(30) Foreign Application Priority Data
Oct. 17, 2013 (KR) 10-2013-0124229

(51) Int. Cl. G03F 1/82; B08B 7/00

(52) U.S. Cl. CPC G03F 1/82; B08B 7/0035
USPC 134/1

(57) ABSTRACT

A method of cleaning a photomask, the method including placing the photomask in a chamber, the photomask including a mask substrate and a reflective layer, a capping layer, and a light absorbing layer pattern stacked on the mask substrate, and wherein the photomask has contaminants thereon; supplying a gas into the chamber such that the gas does not react with the capping layer or reacts with the capping layer to form an anti-oxidant layer; ionizing the gas by irradiating an inside of the chamber with an energy beam such that the contaminants react with the ionized gas to be converted to a by-product; and removing the by-product from the chamber.

### CROSS-REFERENCE TO RELATED APPLICATION

Korean Patent Application No. 10-2013-0124229, filed on Oct. 17, 2013, in the Korean Intellectual Property Office, and entitled: “Method Of Cleaning Photomask,” is incorporated by reference herein in its entirety.

### BACKGROUND

1. Field

Embodiments relate to a method of cleaning a photomask.

2. Description of Related Art

Contaminants may be present on a surface of a photomask that is used in a lithography process for forming a pattern on a semiconductor substrate.

### SUMMARY

Embodiments are directed to a method of cleaning a photomask.

The embodiments may be realized by providing a method of cleaning a photomask, the method including placing the photomask in a chamber, the photomask including a mask substrate and a reflective layer, a capping layer, and a light absorbing layer pattern stacked on the mask substrate, and wherein the photomask has contaminants thereon; supplying a gas into the chamber such that the gas does not react with the capping layer or reacts with the capping layer to form an anti-oxidant layer; ionizing the gas by irradiating an inside of the chamber with an energy beam such that the contaminants react with the ionized gas to be converted to a by-product; and removing the by-product from the chamber.

The gas may contain nitrogen and oxygen.

The gas may include NO, NO₂, N₂O₄, N₂O, N₄O, NO₃, N₂O₃, N₂O₅, or N(NO₂)₃.

The energy beam may include an electron beam, an ion beam, or a laser beam.

The energy beam may be locally irradiated on the photomask.

The energy beam may be widely irradiated on the photomask.

The energy beam may be irradiated into the chamber after the chamber is filled with the gas.

The contaminants may include an organic contaminant that contains carbon.

The by-product may be removed from the chamber with a vacuum pump.

The embodiments may be realized by providing a method of cleaning a photomask, the method including placing the photomask in a chamber, the photomask having contaminants thereon; supplying a gas into the chamber, the gas containing nitrogen and oxygen; ionizing the gas by irradiating an inside of the chamber with an energy beam such that the contaminants react with the ionized gas and are converted to a by-product; and removing the by-product from the chamber.

The gas may include NO, NO₂, N₂O₄, N₂O, N₄O, NO₃, N₂O₃, N₂O₅, or N(NO₂)₃.

The energy beam may include an electron beam, an ion beam, or a laser beam.

The by-product may be removed from the chamber with a vacuum pump.

The photomask may be an extreme ultra-violet mask.

The photomask may be an optical mask.

The embodiments may be realized by providing a method of cleaning a photomask, the method including preparing the photomask, the photomask including carbon-containing contaminants thereon; placing the photomask in a chamber; supplying oxygen ions into the chamber such that the carbon containing contaminants react with the oxygen ions to be converted to a by-product; and removing the by-product from the chamber.

The by-product may include carbon dioxide.

The by-product may be removed from the chamber with a vacuum pump.

Supplying oxygen ions into the chamber may include supplying a gas into the chamber, the gas containing nitrogen and oxygen; and ionizing the gas by irradiating an inside of the chamber with an energy beam.

The gas may include NO, NO₂, N₂O₄, N₂O, N₄O, NO₃, N₂O₃, N₂O₅, or N(NO₂)₃, and the energy beam may include an electron beam, an ion beam, or a laser beam.

### BRIEF DESCRIPTION OF THE DRAWINGS

Features will be apparent to those of skill in the art by describing in detail exemplary embodiments with reference to the attached drawings in which:

FIG. 1 illustrates a schematic diagram of a photomask cleaning apparatus used in an embodiment;

FIGS. 2 and 3 illustrate cross-sectional views of stages in a method of cleaning a photomask in accordance with an embodiment; and

FIGS. 4 and 5 illustrate cross-sectional views of stages in a method of cleaning a photomask in accordance with another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

The terminology used herein to describe embodiments is not intended to limit the scope thereof. The articles “a,” “an,” and “the” are singular in that they have a single referent; however, the use of the singular form in the present document should not preclude the presence of more than one referent. For example, elements referred to in the singular may number one or more, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to,” or “coupled to” another element or layer, it can be directly on, connected to, or coupled to the other element or layer, or intervening elements or layers may be present. In contrast, when an element is referred to as being “directly on,” “directly connected to,” or “directly coupled to” another element or layer, there are no intervening elements or layers present.

Spatially relative terms, such as “beneath,” “below,” “lower,” “above,” “upper,” and the like may be used herein to describe the relationship of one element or feature to another, as illustrated in the drawings. It will be understood that such descriptions are intended to encompass different orientations in use or operation in addition to orientations depicted in the drawings. For example, if a device is turned over, elements described as “below” or “beneath” other elements or features would then be oriented “above” the other elements or features. Thus, the term “below” is intended to mean both above and below, depending upon overall device orientation.

It will be understood that, although the terms first, second, A, B, etc. may be used herein in reference to elements, such elements should not be construed as limited by these terms. For example, a first element could be termed a second element, and a second element could be termed a first element, without departing from the scope of the present invention. Herein, the term “and/or” includes any and all combinations of one or more referents.

Embodiments are described herein with reference to cross-sectional illustrations that are schematic illustrations of idealized embodiments and intermediate structures. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present application.

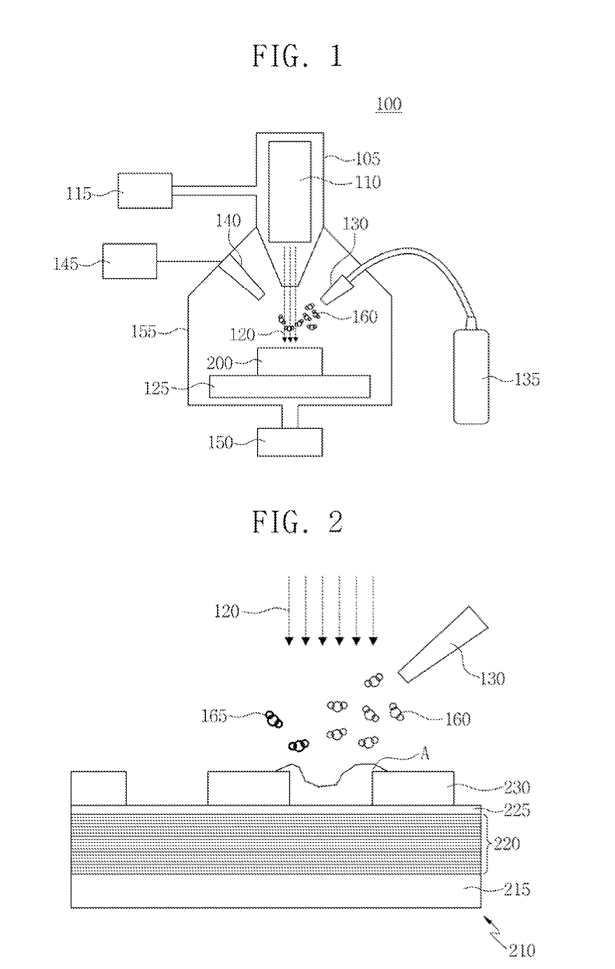

FIG. 1 illustrates a schematic diagram of a photomask cleaning apparatus used in an embodiment.

Referring to FIG. 1, a photomask cleaning apparatus 100 in accordance with an embodiment may include a chamber 155 (in which a photomask 200 to be cleaned may be located), a vacuum pump 150 (for evacuating an inside of the chamber 155), a gas injector 130 (for supplying a gas into the chamber 155), a gas supply 135 (connected to the gas injector 130), and an energy beam irradiation apparatus 105 (for radiating an energy beam 120, e.g., an electron beam, an ion beam, or a laser beam, into the chamber 155).

The photomask 200 may be mounted on a stage 125 that is located in the chamber 155. The photomask 200 may include an extreme ultra-violet (EUV) mask (e.g., a reflective photomask) or an optical mask (e.g., a transmissive photomask).

The stage 125 may be mechanically operated such that the photomask 200 is located under the energy beam 120.

The energy beam irradiation apparatus 105 may be an apparatus that ionizes a gas (that is supplied into the chamber 155 through the gas injector 130) to generate active radicals 160, and may include an optical column 110. The optical column 110 may include, e.g., an energy beam source (e.g., an electron gun that generates an electron beam) and a plurality of lenses and a deflector (which control the shape and direction of the energy beam 120 generated from the energy beam source), such that the energy beam 120 may be irradiated on the photomask 200. The energy beam 120 may be locally or widely irradiated on the photomask 200 by the optical column 110.

The energy beam irradiation apparatus 105 may further include an ion pump 115 for highly vacuumizing the optical column 110.

The photomask cleaning apparatus 100 may further include a detector 140 (which detects the presence of contaminants on the photomask 200), and an image display 145 (which displays an image implemented by the detector 140 to show a contaminated area of the photomask 200, e.g., to a user).

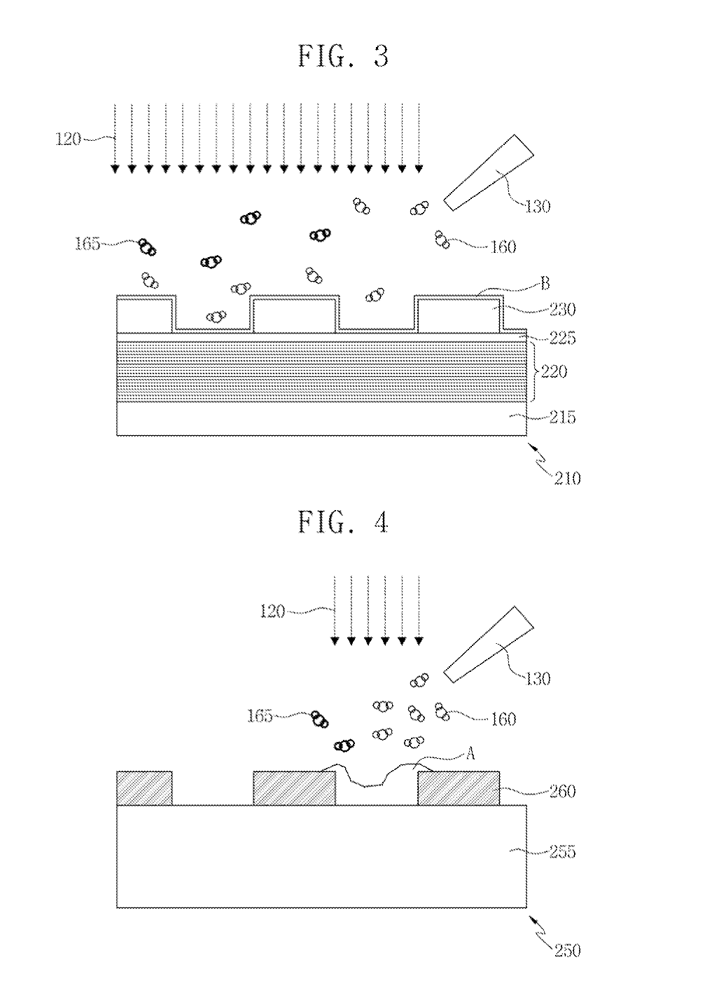

Hereinafter, methods of cleaning a photomask using the photomask cleaning apparatus 100 of FIG. 1 in accordance with various embodiments will be described with reference to FIGS. 2 to 5.

Referring to FIGS. 1, 2, and 3, a method of cleaning a photomask in accordance with an embodiment may include placing an EUV mask in the chamber 155 of the photomask cleaning apparatus 100 of FIG. 1.

As a design rule of a semiconductor device is sharply reduced, a wavelength of light used in an exposure process may also be reduced. EUV light (having a wavelength of 13.5 nm) may be used in the exposure process. The EUV light may have high energy, and it may be absorbed by most materials due to an atomic resonance. A transmissive optical mask (used in other exposure processes) may not be used in the EUV exposure process, and a reflective EUV photomask may be used.

The EUV mask 210 may include a mask substrate 215, and a reflective layer 220, a capping layer 225, and a light-absorbing layer pattern 230 stacked on the mask substrate 215.

The mask substrate 215 may be a transparent substrate including, e.g., silicon or quartz.

The reflective layer 220 may be a layer for reflecting incident light, e.g., EUV light, in the exposure process, and may include a multilayer in which two kinds of different layers are alternately stacked. For example, the reflective layer 220 may be a multilayer in which about forty to sixty silicon layers and molybdenum layers are alternately stacked.

The light-absorbing layer pattern 230 may be a layer that absorbs EUV light to form a pattern. Areas of the reflective layer 220 that are exposed by the light-absorbing layer patterns 230 may be defined as reflective areas. The light-absorbing layer pattern 230 may have a thickness that is suitable for minimizing a shadow effect. The light-absorbing layer pattern 230 may include a material having a very low reflectivity (less than 1%) with respect to light of the EUV wavelengths. In an implementation, the light-absorbing layer pattern 230 may include, e.g., tantalum nitride (TaN), tantalum (Ta), titanium nitride (TiN), titanium (Ti), tantalum silicon (TaSi), or tantalum silicon nitride (TaSiN).

The capping layer 225 may be between the light-absorbing layer pattern 230 and the reflective layer 220. The capping layer 225 may help protect the reflective layer 220 from an etch process when forming the light-absorbing layer pattern 230, and may help prevent oxidation of the reflective layer 220. The capping layer 225 may include a material having a high etch selectivity to the light-absorbing layer pattern 230 and a high oxidation resistance, e.g., ruthenium (Ru).

The EUV mask 210 may further include an anti-reflection layer (not shown) on the light-absorbing layer pattern 230. The anti-reflection layer may include, e.g., aluminum oxide (Al₂O₃), silicon oxynitride (SiON), or tantalum boron nitride (TaBN).

The EUV mask 210 may have contaminants thereon (A of FIG. 2 and B of FIG. 3). The contaminants A and B may include, e.g., organic contaminants that contain carbon. For example, when inspecting a mask using a scanning electron microscope (SEM) for surface evaluation, the SEM may form carbon-containing contaminants or generate unwanted electrostatic charges on a scanned surface during the surface evaluation of the mask. In some cases, e.g., as shown in FIG. 3, the SEM inspection may leave film-type carbon-containing contaminants (B) on the scanned surface of the mask. The electrostatic charges accumulated on the surface of the mask may attract airborne contaminants.

For example, during a mask manufacturing process, the electrostatic charges may be accumulated on a surface of the mask, and airborne carbon-containing contaminants may be attached on the surface of the mask. In this case, the carbon-containing contaminants may be in the form of lumps A, as shown in FIG. 2.

The contaminants A and B on the EUV mask 210 may interfere with transmission or reflection of incident light during the exposure process, which may cause variation in line widths and profiles of patterns. Accordingly, a critical dimension (CD) of a pattern of a semiconductor device may undesirably fluctuate.

In order to remove the contaminants A and B on the surface of the EUV mask 210, the EUV mask 210 may be placed on the stage 125 in the chamber 155 of the photomask cleaning apparatus 100 shown in FIG. 1.

The inside of the chamber 155 may be evacuated by turning on a vacuum pump 150 of the photomask cleaning apparatus 100.

Next, a valve connected to the gas supply 135 of the photomask cleaning apparatus 100 may be opened, and then a gas may be supplied from the gas supply 135 into the chamber 155 through the gas injector 130.

In an implementation, the gas supplied into the chamber 155 may be a gas that does not react with or is inert with respect to the capping layer 225 of the EUV mask 210. In an implementation, the gas may react with the capping layer 225 to only form an anti-oxidant layer. In an implementation, the gas may include nitrogen (N) and oxygen (O). For example, the gas may include an NₓO_{y} gas, such as NO, NO₂, N₂O₄, N₂O, N₄O, NO₃, N₂O₃, N₂O₅, or N(NO₂)₃.

When the inside of the chamber 155 is fully filled with the gas, the energy beam 120 (generated from the energy beam irradiation apparatus 105 of the photomask cleaning apparatus 100) may be irradiated into the chamber 155 and directed to the EUV mask 210. The energy beam 120 may include, e.g., an electron beam, an ion beam, or a laser beam. In an implementation, when the contaminants on the EUV mask 210 exist in the form of lumps (A), the energy beam 120 may be locally or selectively irradiated as shown in FIG. 2, e.g., only the lumps (A) may be selectively irradiated with the energy beam 120 without irradiating other parts of the EUV mask 210. In an implementation, when the contaminants on the EUV mask 210 exist in the form of a long film (B), the energy beam 120 may be widely irradiated as shown in FIG. 3, e.g., the energy beam 120 may irradiate a large portion of or an entire area of the EUV mask 210.

The energy beam 120 irradiated into the chamber 155 may ionize the gas inside of the chamber 155 to generate active radicals 160. The active radicals 160 may react with the contaminants A and B, e.g., carbon-containing contaminants, on the EUV mask 210 to convert the contaminants A and B to a gaseous by-product 165.

In an implementation, when a gas containing nitrogen (N) and oxygen (O), e.g., nitrogen dioxide (NO₂), is supplied into the chamber 155, and then the energy beam 120 is irradiated into the chamber 155, the NO₂ gas may be ionized as shown in following reaction formula (1) to be decomposed into a nitrogen monoxide ion (NO⁻) and an oxygen ion (O⁻).

NO₂(g)→NO⁻+O⁻ formula (1)

Oxygen ion radicals generated from the ionized NO₂ gas may oxidize carbon of the carbon-containing contaminants A and B on the EUV mask 210, as shown in following reaction formula (2).

C+O⁻→COₓ(g) formula (2)

Accordingly, the oxidized carbon-containing contaminants A and B may be converted to the gaseous by-product 165, e.g., carbon dioxide CO₂.

In an implementation, the NO₂ gas supplied to the chamber 155 may react with the capping layer 225 of the EUV mask 210, e.g., the capping layer 225 formed of ruthenium (Ru), as shown in following reaction formula (3).

Ru+4NO₂(g)→Ru(NO₃)₂+2NO(g) formula (3)

The Ru(NO₃)₂ layer may function as an anti-oxidant layer without damaging the Ru capping layer 225.

The amount of radicals 160 generated for oxidizing the carbon-containing contaminants on the EUV mask 210 may be controlled according to a strength or intensity of the energy beam 120.

As described above, when the EUV mask 210 is irradiated with the energy beam 120 for a certain time, the contaminants A and B on the EUV mask 210 may be converted to the gaseous by-product 165, and the gaseous by-product 165 may be removed from the chamber 155 to be released out. For example, the vacuum pump 150 may be used to evacuate the chamber 155 (that includes the gaseous by-product 165 therein).

According to the method of cleaning a photomask in accordance with the embodiments, a gas containing, e.g., nitrogen (N) and oxygen (O), may be supplied into the chamber 155 in which the EUV mask 210 is placed, and an energy beam, e.g., an electron beam, an ion beam, or a laser beam, may be irradiated into the chamber 155 to ionize the gas containing, e.g., nitrogen (N) and oxygen (O). Then, the radicals 160 generated from the ionized gas may react with the contaminants A and B on the EUV mask 210, and thus the contaminants A and B may be converted to the gaseous by-product 165. The gaseous by-product 165 may be removed from the chamber 155 using the vacuum pump 150.

The gas supplied into the chamber 155 may not react with the capping layer 225 of the EUV mask 210 (or may react with the capping layer 225 to only form an anti-oxidant layer), and the capping layer 225 of the EUV mask 210 may not be damaged. Accordingly, the contaminants on the EUV mask 210 may be selectively removed without damaging the capping layer 225.

Referring to FIGS. 1, 4, and 5, a method of cleaning a photomask in accordance with another embodiment may include placing an optical mask 250 (e.g., a transmissive photomask) in the chamber 155 of the photomask cleaning apparatus 100 of FIG. 1.

The optical mask 250 may include a mask substrate 255 and a light-shielding pattern 260 on the mask substrate 255.

The mask substrate 255 may be a transparent substrate including, e.g., silicon or quartz.

The light-shielding pattern 260 may be a layer for defining a transmissive area and a light-shielding area on the mask substrate 255, and may include, e.g., chromium (Cr).

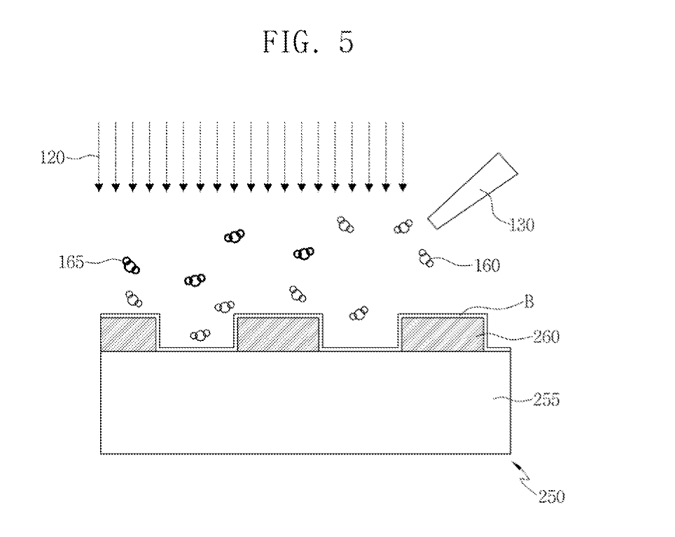

The optical mask 250 may have contaminants (A in FIG. 4 and B in FIG. 5). The contaminants A and B may include, e.g., carbon-containing organic contaminants. The contaminants A and B, e.g., the carbon-containing organic contaminants, may be attached, deposited, or otherwise formed on the optical mask 250 during, e.g., a mask inspection process using a SEM, or a mask fabrication process.

Contaminants A (e.g., from airborne contaminants), formed during the mask fabrication process, may exist in the form of lumps, as shown in FIG. 4. The SEM inspection may generate, e.g., film-type contaminants B, as shown in FIG. 5.

The contaminants A and/or B on the optical mask 250 may interfere with transmission of incident light during the exposure process, which may cause variation in a line width and profile of a pattern. In order to remove the contaminants A and/or B, the optical mask 250 may be placed on the stage 125 in the chamber 155 of the photomask cleaning apparatus 100 shown in FIG. 1.

The inside of the chamber 155 may be evacuated by turning on the vacuum pump 150 of the photomask cleaning apparatus 100.

Next, a valve connected to the gas supply 135 of the photomask cleaning apparatus 100 may be opened, and then a gas may be supplied from the gas supply 135 into the chamber 155 through the gas injector 130.

The gas supplied into the chamber 155 may contain, e.g., nitrogen (N) and oxygen (O). For example, the gas may include an NₓO_{y} gas, such as NO, NO₂, N₂O₄, N₂O, N₄O, NO₃, N₂O₃, N₂O₅, or N(NO₂)₃.

When the inside of the chamber 155 is fully filled with the gas containing, e.g., nitrogen (N) and oxygen (O), an energy beam 120 (generated from the energy beam irradiation apparatus 105 of the photomask cleaning apparatus 100) may be irradiated into the chamber 155 and directed to the optical mask 250. The energy beam 120 may include, e.g., an electron beam, an ion beam, or a laser beam. In an implementation, when the contaminants on the optical mask 250 exist in the form of lumps (A), the energy beam 120 may be locally or selectively irradiated as shown in FIG. 4, e.g., the energy beam 120 may be selectively irradiated only on the lumps (A), without irradiating other portions of the mask 250. In an implementation, when the contaminants on the optical mask 250 exist in the form of a long film (B), the energy beam 120 may be widely irradiated, as shown in FIG. 5, e.g., the energy beam 120 may be irradiated on a large portion of or an entire area of the mask 250.

The energy beam 120 irradiated into the chamber 155 may ionize the gas that fills the inside of the chamber 155 to generate active radicals 160. The radicals 160 may react with the contaminants A and B, e.g., the carbon-containing contaminants on the EUV mask 210, to convert the contaminants A and B to a gaseous by-product 165.

For example, when nitrogen dioxide (NO₂) gas is supplied into the chamber 155, and then the energy beam 120 is irradiated, the NO₂ gas may be ionized to generate oxygen ion radicals. The oxygen ion radicals may oxidize carbon of the carbon-containing contaminants A and B on the optical mask 250 to convert the carbon-containing contaminants A and B to a gaseous by-product 165, e.g., carbon dioxide CO₂.

The gaseous by-product 165 (generated by irradiating the optical mask 250 with the energy beam 120 for a certain time) may be removed from the chamber 155 to be released out. For example, the vacuum pump 150 may be used to then clear the inside of the chamber 155 (including the gaseous by-product 165).

According to the method of cleaning a photomask in accordance with the other embodiment, a gas including, e.g., nitrogen (N) and oxygen (O), may be supplied into the chamber 155 in which the optical mask 250 is placed, and an energy beam, e.g., an electron beam, an ion beam, or a laser beam, may be irradiated into the chamber 155 to ionize the gas containing nitrogen (N) and oxygen (O). Then, the radicals 160 generated from the ionized gas may react with the contaminants A and B on the optical mask 250, and thus the contaminants A and B may be converted to the gaseous by-product 165. The gaseous by-product 165 may be removed from the chamber 155 using the vacuum pump 150, and the contaminants may be effectively removed without damaging the optical mask 250.

According to various embodiments, a gas containing, e.g., nitrogen (N) and oxygen (O), may be ionized using an energy beam, e.g., an electron beam, an ion beam, or a laser beam, and radicals generated from the ionized gas may react with contaminants on a surface of a mask. Thus, the contaminants may be converted to a gaseous by-product. Accordingly, loss of a mask surface or damage of a mask pattern may be prevented, and the contaminants on the mask may be effectively removed.

By way of summation and review, contaminants may affect transmittance of the photomask, and may cause variation in a line width and profile of the pattern. A method of cleaning a photomask according to an embodiment may help minimize or remove a mask defect generated by the contaminants.

The embodiments may provide a method of cleaning contaminants from a photomask.

The embodiments may provide a method of cleaning a photomask, which may effectively remove contaminants on a mask.

The embodiments may provide a method of cleaning a photomask, which may help prevent loss of a mask surface or damage of a mask pattern.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of cleaning a photomask, the method comprising:
placing the photomask in a chamber, the photomask including a mask substrate and a reflective layer, a capping layer, and a light absorbing layer pattern stacked on the mask substrate, and wherein the photomask has contaminants thereon;
supplying a gas into the chamber such that the gas does not react with the capping layer or reacts with the capping layer to form an anti-oxidant layer;
ionizing the gas by irradiating an inside of the chamber with an energy beam such that the contaminants react with the ionizing gas be converted to a by-product; and
removing the by-product from the chamber.

2. The method as claimed in claim 1, wherein the gas contains nitrogen and oxygen.

3. The method as claimed in claim 2, wherein the gas includes NO, NO₂, N₂O₄, N₂O, N₄O, NO₃, N₂O₃, N₂O₅, or N(NO₂)₃.

4. The method as claimed in claim 1, wherein the energy beam includes an electron beam, an ion beam, or a laser beam.

5. The method as claimed in claim 1, wherein the energy beam is locally irradiated on the photomask.

6. The method as claimed in claim 1, wherein the energy beam is widely irradiated on the photomask.

7. The method as claimed in claim 1, wherein the energy beam is irradiated into the chamber after the chamber is filled with the gas.

8. The method as claimed in claim 1, wherein the contaminants include an organic contaminant that contains carbon.

9. The method as claimed in claim 1, wherein the by-product is removed from the chamber with a vacuum pump.

10. A method of cleaning a photomask, the method comprising:
placing the photomask in a chamber, the photomask having contaminants thereon;
supplying a gas into the chamber, the gas containing nitrogen and oxygen;
ionizing the gas by irradiating an inside of the chamber with an energy beam such that the contaminants react with the ionized gas and are converted to a by-product; and
removing the by-product from the chamber.

11. The method as claimed in claim 10, wherein the gas includes NO, NO₂, N₂O₄, N₂O, N₄O, NO₃, N₂O₃, N₂O₅, or N(NO₂)₃.

12. The method as claimed in claim 10, wherein the energy beam includes an electron beam, an ion beam, or a laser beam.

13. The method as claimed in claim 10, wherein the by-product is removed from the chamber with a vacuum pump.

14. The method as claimed in claim 10, wherein the photomask is an extreme ultra-violet mask.

15. The method as claimed in claim 10, wherein the photomask is an optical mask.

16. A method of cleaning a photomask, the method comprising:
preparing the photomask, the photomask including carbon-containing contaminants thereon;
placing the photomask in a chamber;
supplying oxygen ions into the chamber such that the carbon containing contaminants react with the oxygen ions to be converted to a by-product; and
removing the by-product from the chamber.

17. The method as claimed in claim 16, wherein the by-product includes carbon dioxide.

18. The method as claimed in claim 16, wherein the by-product is removed from the chamber with a vacuum pump.

19. The method as claimed in claim 16, wherein supplying oxygen ions into the chamber includes:
supplying a gas into the chamber, the gas containing nitrogen and oxygen; and
ionizing the gas by irradiating an inside of the chamber with an energy beam.

20. The method as claimed in claim 19, wherein:
the gas includes NO, NO₂₉N₂O₄, N₂O, N₄O, NO₃, N₂O₃, N₂O₅, or N(NO₂)₃, and
the energy beam includes an electron beam, an ion beam, or a laser beam.
